(19) United States
(12) Patent Application Publication
(10) Pub. No.: US 2025/0350142 A1
(43) Pub. Date: Nov. 13, 2025

(54) CHARGER WITH DATA COLLECTION FUNCTION FOR OCV DEGRADATION ANALYSIS, AND METHOD OF ACQUIRING OCV DATA

(71) Applicant: MURATA MANUFACTURING CO., LTD., Kyoto (JP)

(72) Inventors: Koji HATTORI, Kyoto (JP); Asuki YANAGIHARA, Kyoto (JP)

(21) Appl. No.: 19/263,142

(22) Filed: Jul. 8, 2025

Related U.S. Application Data
(63) Continuation of application No. PCT/JP2023/039281, filed on Oct. 31, 2023.

(30) Foreign Application Priority Data
Feb. 27, 2023 (JP) 2023-027968

(51) Int. Cl. H02J 7/00; H01M 4/02; H01M 4/505; H01M 4/525; H01M 4/583; H01M 10/0525

(52) U.S. Cl. CPC H02J 7/007186; H02J 7/0048; H02J 7/005; H02J 7/0063; H02J 7/007184; H01M 2004/027; H01M 2004/028; H01M 4/505; H01M 4/525; H01M 4/583; H01M 10/0525

(57) ABSTRACT

A first mode is a mode in which a secondary battery (90) is charged at a predetermined current value for a first time period, and a terminal voltage value (α) of the secondary battery (90) immediately after the lapse of the first time period is measured. A second mode is a mode in which the charging is stopped for a second time period after execution of the first mode, and an OCV value (β) of the secondary battery (90) immediately after the lapse of the second time period is measured. A determination unit (24) compares a current terminal voltage value (αA) measured in the first mode with a previous terminal voltage value (αB) measured in the immediately previous first mode. When the first time period is a (minute) and the predetermined current value is I (C), the determination unit (24) determines not to shift to the second mode in a case where αA/αB<(a×I/250)+1 (0.5≤a≤3, 0.4≤I≤2.4, and 0.6≤a×I≤1.2). The determination unit (24) determines to shift to the second mode in a case where αA/αB≥(a×I/250)+1 (0.5≤a≤3, 0.4≤I≤2.4, and 0.6≤a×I≤1.2). A measuring unit (22) measures the OCV value (β) in the second mode.

### CROSS REFERENCE TO RELATED APPLICATIONS

The present application is a continuation of International Application No. PCT/JP2023/039281, filed on Oct. 31, 2023, which claims priority to Japanese Patent Application No. 2023-027968, filed on Feb. 27, 2023, the entire contents of which are incorporated herein by reference.

### BACKGROUND

The present disclosure relates to a technique for reducing acquisition time of OCV data for OCV degradation analysis, which is one of methods for analyzing degradation of a secondary battery.

Conventionally, various methods for analyzing a charging state using SOC and OCV are considered.

In order to acquire OCV data (OCV value group) for an SOC-OCV characteristic (SOC-OCV curve) used for such analysis, it has been common to perform intermittent charging while setting a sufficient relaxation time (pause time).

### SUMMARY

The present disclosure relates to a technique for reducing acquisition time of OCV data for OCV degradation analysis, which is one of methods for analyzing degradation of a secondary battery.

The relaxation time described above depends on a structure of a secondary battery, but it takes 20 minutes to 30 minutes. Therefore, it takes a lot of time if an attempt is made to measure OCV voltages at short intervals between 0% and 100% of SOC. For example, in a case where the SOC is divided into 60 from 0% to 100% and intermittent charging is performed by performing charging at a 1 C rate for 1 minute with a pause of 20 minutes, it takes 21 hours.

However, Patent Document 1 does not describe a method of reducing the time for measuring the OCV voltages for generation of the SOC-OCV characteristic.

In addition, if a method of simply reducing the number of divisions of measurement or a method of not providing the relaxation time in a partial period is adopted, a difference in fitting accuracy (degree of matching) between an SOC-OCV curve obtained from measured values and an SOC-OCV curve as a reference increases.

In an embodiment, the present disclosure relates to reducing acquisition time of OCV data while suppressing an increase in analytical error in OCV degradation analysis.

A charger of the present disclosure, in an embodiment, includes a measuring unit, a storage unit, a determination unit, a charge control unit, and an output unit. The measuring unit measures a terminal voltage value α for mode selection and an OCV value β for a lithium ion secondary battery. The storage unit stores the measured terminal voltage value α for mode selection and OCV value β. The determination unit determines selection between a first mode and a second mode based on the terminal voltage value α for mode selection. The charge control unit performs charge control of the lithium ion secondary battery in the first mode or the second mode based on the determination result. The output unit outputs at least one OCV value β measured in the process of charging as OCV data.

The first mode is a mode in which the lithium ion secondary battery is charged at a predetermined current value for a first time period and the terminal voltage value α of the lithium ion secondary battery immediately after the lapse of the first time period is measured. The second mode is a mode in which the charging is stopped for a second time period after execution of the first mode and the OCV value β of the lithium ion secondary battery immediately after the second time period elapses is measured.

The determination unit compares a current terminal voltage value αA measured in the first mode with a previous terminal voltage value αB measured in the immediately previous first mode.

When the first time period is a (minute) and the predetermined current value is I (C), the determination unit determines
not to shift to the second mode in a case where

$$α A / α B < ( a \times I / 250 ) + 1 ,$$

$$( 0.5 \leq a \leq 3 , 0.4 \leq I \leq 2.4 , and 0.6 \leq a \times I \leq 1.2 ) ,$$

and
to shift to the second mode in a case where

$$α A / α B \geq ( a \times I / 250 ) + 1$$

$$( 0.5 \leq a \leq 3 , 0.4 \leq I \leq 2.4 , and 0.6 \leq a \times I \leq 1.2 ) .$$

The measuring unit measures the OCV value β in the second mode.

In this configuration, when a change rate of the terminal voltage value for mode selection is smaller than a threshold set based on a charging time and a charging current value, the measurement of the OCV value β is omitted. The highly accurate measurement of the OCV value β requires execution of the second mode, that is, a relaxation time (charging pause time) of the second time period with respect to the charging time. Therefore, as the number of times of measurement of the OCV value β decreases, the time required to acquire the OCV data is reduced.

Further, when the change rate of the terminal voltage value for mode selection is small, the change of the OCV value β is small with respect to the change of the SOC. Therefore, even if the measurement of the OCV value β is omitted when the change rate of the terminal voltage value for mode selection is small, error in the OCV degradation analysis can be suppressed to be small.

According to the present disclosure, it is possible to reduce the acquisition time of the OCV data while suppressing the increase in the analytical error in the OCV degradation analysis according to an embodiment.

### BRIEF DESCRIPTION OF THE FIGURES

FIG. 1 is a configuration diagram of a charging system that includes a charger and a secondary battery and is capable of acquiring OCV data according to an embodiment of the present disclosure.

FIG. 2 is a graph showing an example of a relationship between Soc and a charging voltage value.

FIG. 3 is a graph showing an example of a relationship between the SOC and a voltage change rate.

FIG. 4 is a graph showing a relationship between the voltage change rate, a reduction rate of OCV data acquisition time, and the maximum error of a parameter calculated by performing degradation analysis using acquired OCV data.

FIG. 5 is a flowchart illustrating an example of a method of acquiring OCV data according to an embodiment of the present disclosure.

FIG. 6 includes views (A) and (B), where view (A) is a graph showing an example of a voltage change rate with respect to SOC of a positive electrode active material of a secondary battery according to an embodiment of the present disclosure, and where view (B) is a graph showing an example of a voltage change rate with respect to SOC of a negative electrode active material of the secondary battery according to an embodiment of the present disclosure.

FIG. 7 includes views (A), (B), (C) and (D), where views (A), (C), and (D) are tables showing a relationship between a time reduction rate and a combination of SOC ranges in which a second mode is performed, and where view (B) is a table showing a relationship between the combination of SOC ranges in which the second mode is performed and the maximum error of a parameter calculated by performing degradation analysis using acquired OCV data.

FIG. 8 includes views (A) and (B), where view (A) is a table showing a relationship between a time reduction rate and a combination of the lowest SOC and the highest SOC in a low SOC range in which a second mode is performed, and where view (B) is a table showing a relationship between the combination of the lowest SOC and the highest SOC in the low SOC range in which the second mode is performed and the maximum error of a parameter calculated by degradation analysis using acquired OCV data.

### DETAILED DESCRIPTION

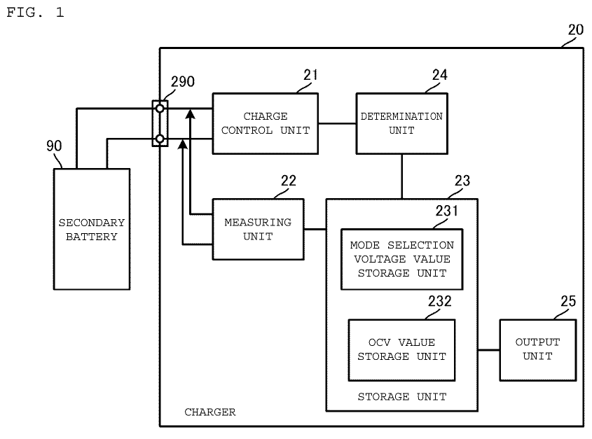

A charger and a method of acquiring OCV data according to a first embodiment of the present disclosure will be described with reference to the drawings. FIG. 1 is a configuration diagram of a charging system that includes the charger and a secondary battery and is capable of acquiring OCV data according to the first embodiment of the present disclosure.

As illustrated in FIG. 1, a charger 20 includes a charge control unit 21, a measuring unit 22, a storage unit 23, a determination unit 24, an output unit 25, and a charge terminal 290. In addition, the charger 20 is supplied with power from a commercial power source or the like although not illustrated.

A secondary battery 90 is, for example, a lithium ion secondary battery. The secondary battery 90 is charged by being connected to the charge terminal 290.

The charge control unit 21 charges the secondary battery 90 connected to the charge terminal 290. At this time, the charge control unit 21 performs charge control according to a mode determined by the determination unit 24. The mode includes a first mode and a second mode.

The measuring unit 22 measures terminal voltage values of the secondary battery 90. More specifically, the measuring unit 22 measures a terminal voltage value α for mode selection and an OCV value β as the terminal voltage values of the secondary battery 90. The measuring unit 22 measures the terminal voltage value α for mode selection in the first mode, and measures the OCV value β in the second mode.

The measuring unit 22 outputs the measured terminal voltage value α for mode selection and OCV value β to the storage unit 23.

The storage unit 23 includes a mode selection voltage value storage unit 231 and an OCV value storage unit 232. The mode selection voltage value storage unit 231 stores the terminal voltage value α for mode selection. The OCV value storage unit 232 stores the OCV value β.

The determination unit 24 determines selection between the first mode and the second mode based on the terminal voltage value α for mode selection. The determination unit 24 outputs the determined mode to the charge control unit 21.

The output unit 25 acquires at least one OCV value β, measured in the pause process after charging, from the OCV value storage unit 232 as OCV data and outputs the OCV data.

The first mode is a mode in which the secondary battery 90 is charged at a predetermined current value for a first time period and the terminal voltage value α of the secondary battery 90 immediately after the lapse of the first time period is measured.

The charge control unit 21 charges the secondary battery 90 at the predetermined current value for the first time period (for example, 1 minute). The measuring unit 22 measures a terminal voltage value of the secondary battery 90 immediately after the lapse of the first time period as the terminal voltage value α for mode selection. The measuring unit 22 outputs the measured terminal voltage value α for mode selection to the storage unit 23. The mode selection voltage value storage unit 231 of the storage unit 23 stores the terminal voltage value α for mode selection.

The second mode is a mode in which charging is stopped for a second time period after execution of the first mode and the OCV value β of the secondary battery 90 immediately after the lapse of the second time period is measured.

After performing charge control in the above-described first mode, the charge control unit 21 stops charging for the second time period (for example, 10 minutes, 20 minutes, or 30 minutes). This second time period corresponds to a so-called relaxation time or pause time.

The measuring unit 22 measures, as the terminal voltage value α for mode selection, a terminal voltage value of the secondary battery 90 immediately after the charge control unit 21 performs the charge control in the first mode. Thereafter, the measuring unit 22 further measures, as the OCV value β, a terminal voltage value of the secondary battery 90 immediately after the lapse of the second time period. The measuring unit 22 outputs the measured terminal voltage value α for mode selection and OCV value β to the storage unit 23. The mode selection voltage value storage unit 231 of the storage unit 23 stores the terminal voltage value α for mode selection, and the OCV value storage unit 232 stores the OCV value β.

Specifically, the determination unit 24 determines the selection of the first mode and the second mode by the following method.

The determination unit 24 reads a current terminal voltage value αA and a previous terminal voltage value αB (immediately previous terminal voltage value) measured in the immediately previous first mode from the mode selection voltage value storage unit 231. The determination unit 24 calculates a ratio (αA/αB) between the current terminal voltage value αA and the immediately previous terminal voltage value αB.

The determination unit 24 calculates (a×I/250)+1 with the first time period as a (minute) and the predetermined current value as I (C).

The determination unit 24 determines not to shift to the second mode in a case where

$$α A / α B < ( a \times I / 250 ) + 1$$

$$( 0.5 \leq a \leq 3 , 0.4 \leq I \leq 2.4 , and 0.6 \leq a \times I \leq 1.2 ) .$$

The determination unit 24 determines to shift to the second mode in a case where

$$α A / α B \geq ( a \times I / 250 ) + 1$$

$$( 0.5 \leq a \leq 3 , 0.4 \leq I \leq 2.4 , and 0.6 \leq a \times I \leq 1.2 ) .$$

In an electrode active material constituting the secondary battery 90, an OCV value (voltage value) changes with a change in a crystal structure or a change in the content of lithium ions. The OCV analysis is an analysis method capable of estimating degradation states and a combination state of positive and negative electrode materials by fitting an acquired curve of OCV values of a battery with reference data using a reference curve of OCV values of the positive and negative electrode active materials as the reference data.

Therefore, what is required for the analysis is an OCV value in a range with a characteristic structural change (OCV voltage value change) of the positive/negative electrode active material, and an OCV value in a range without any particular structural change (voltage change) is not so important for the analysis.

Therefore, if the OCV value in the range with the characteristic structural change (OCV voltage value change) of the positive/negative electrode active material can be measured, the fitting with high accuracy is possible, and the OCV analysis with high accuracy can be achieved. On the other hand, if the measurement of the OCV value in the range without any particular structural change (voltage change) is omitted, the number of times of acquisition of OCV data points can be reduced while suppressing a decrease in analysis accuracy.

In addition, an overvoltage is generated during charging depending on the internal resistance of the secondary battery 90. When a charging current is stopped, a voltage of the secondary battery 90 gradually decreases by the overvoltage, and settles at a certain voltage value. This voltage value corresponds to the OCV value β. Therefore, in the case of measuring the OCV value β, it is necessary to repeat charging and a pause while stopping charging until the settlement at the OCV value β. Such a stopping time (relaxation time or pause time) varies depending on the design and material to be used of the secondary battery 90, and a long time of 10 minutes or more is required. Therefore, if many OCV values β are measured between 0% and 100% of SOC, a lot of measurement time is required. Therefore, the total time for acquisition of OCV data can be reduced by omitting the measurement of the OCV value in the range without any particular structural change (voltage change) as described above.

For such an introduction concept, the above-described determination formula is set as follows.

The practical number of divisions for performing the OCV analysis with predetermined accuracy is considered to be “50 or more and 100 or less”. The analysis accuracy decreases if the number of divisions is too small, and the acquisition time of OCV data extends if the number of divisions is too large.

When the second time period (pause time) is b (minute), the total time taken for acquisition of OCV data for acquiring an SOC-OCV characteristic is

$$60 \times ( a + b ) / ( a \times I ) [ minute ] ,$$

and calculated in terms of hours as

$$( a + b ) / ( a \times I ) [ hour ] .$$

When considering a delay of a circuit operation of the charge control unit 21, that the secondary battery 90 is easily degraded when being charged with a large current, that a size of a power supply circuit increases as the current becomes larger, and the like, about 2 C is appropriate as an upper limit, and one charging time is required to be 30 seconds or more. On the other hand, charging with a small current for a long time is a factor of extending the acquisition time of OCV data, and thus it is appropriate to set the upper limit of one charging time to 3 minutes.

In addition, when the charging current I becomes too large, the pause time b needs to be lengthened, and thus, 0.4 C or more and 2.4 C or less is appropriate as calculated from the above-described formula of division points.

As described above, if a is 30 seconds or more and 3 minutes or less (0.5≤a≤3.0) and I is 0.4 C or more and 2.4 C or less (0.4≤I≤2.4), that is, if the relational expression of 0.6≤a×I≤1.2 is satisfied, the measurement can be set to be completed within one night (8 hours) while suppressing a decrease in measurement accuracy.

Using the above concept, the determination unit 24 sets a reference value ((a×I/250)+1) of a change rate by adding one to the product of a×I set as described above and a predetermined correction coefficient (for example, 1/250 in the case of the above formula). This reference value takes into consideration the number of times of measurement and the measurement time, and is a reference value for the ratio (αA/αB) between the current terminal voltage value αA and the immediately previous terminal voltage value αB, and for how much the current terminal voltage value αA has increased from the immediately previous terminal voltage value αB (how much voltage has changed).

Then, when the reference value set as described above is used, the determination unit 24 can determine that it is a range in which the change in the voltage value is large if the ratio (αA/αB) is equal to or more than the reference value ((a×I/250)+1). On the other hand, if the ratio (αA/αB) is less than the reference value ((a×I/250)+1), the determination unit 24 can determine that it is a range in which the change in the voltage value is small.

In this manner, the charger 20 can reduce the acquisition time of OCV data while suppressing an increase in analytical error by performing the above-described configuration and processing.

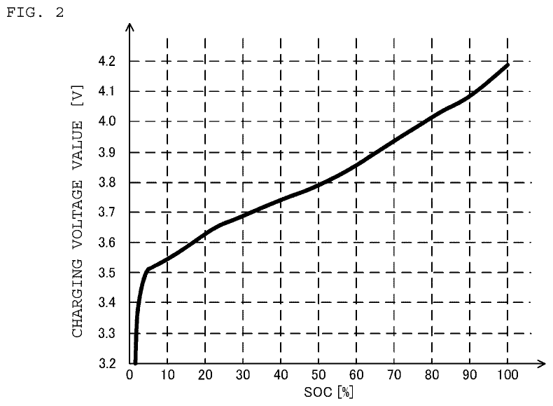

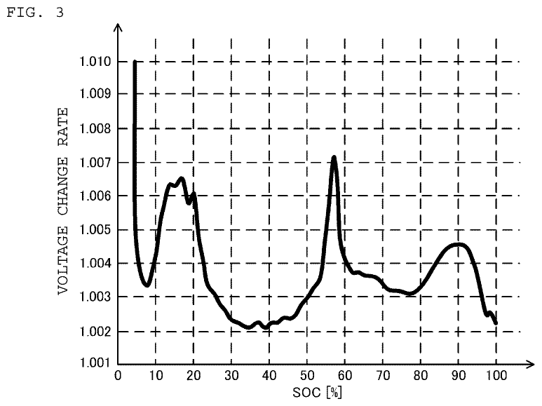

FIG. 2 is a graph showing an example of a relationship between the SOC and a charging voltage value. FIG. 3 is a graph showing an example of a relationship between the SOC and a voltage change rate. FIG. 3 is based on FIG. 2. This voltage change rate corresponds to the above-described ratio (αA/αB).

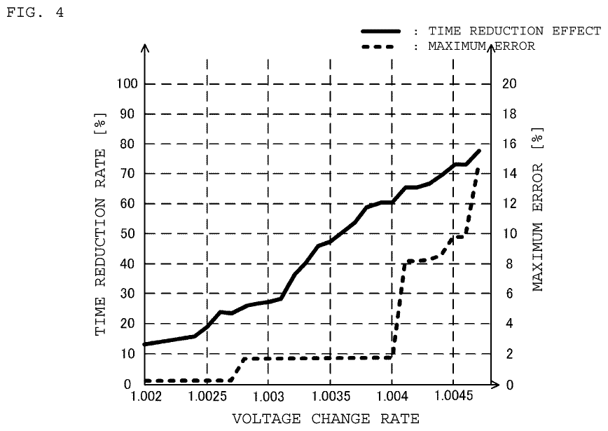

FIG. 4 is a graph showing a relationship among the voltage change rate, a time reduction rate, and the maximum error. A solid line in FIG. 4 indicates the time reduction rate, and a broken line indicates the maximum error. FIG. 4 shows the time reduction rate and the maximum error of the OCV analysis in a case where the measurement of the OCV value is omitted when the voltage change rate is smaller than a reference. The horizontal axis corresponds to the voltage change rate as the reference, and the vertical axis indicates the time reduction rate and the maximum error of the OCV analysis when an OCV value in a range where the voltage change rate is equal to or larger than the reference is measured while omitting measurement of an OCV value in a range where the voltage change rate is smaller than the reference with the voltage change rate indicated by the horizontal axis as the reference. In addition, the time reduction rate indicates how much the ratio can be reduced, assuming that a case where the OCV value measurement is not omitted is 0% and a case where the OCV value measurement is entirely omitted is 100%. That is, the time reduction rate shown in FIG. 4 means that the larger the value, the greater a time reduction effect.

As shown in FIGS. 2 and 3, the voltage change rate varies depending on the SOC. That is, while the SOC changes from 0% to 100%, there are a range in which the voltage change rate is large and a range in which the voltage change rate is small.

Then, as shown in FIG. 4, the time reduction effect and the maximum error change as the reference of the voltage change rate is changed. When the reference of the voltage change rate is increased, the time reduction effect is improved, but the maximum error increases. Conversely, when the reference of the voltage change rate is decreased, the maximum error is reduced, but the time reduction effect is suppressed.

Therefore, for example, when the voltage change rate is set to 1.004 based on the above-described formula, OCV data can be acquired with 60% of time as compared with a case where the second mode is performed at all the division points, and the maximum error can be suppressed to 2% or less.

Note that the charger 20 preferably includes an electronic load connectable to the charge terminal 290.

The charge control unit 21 starts charge control in the first mode after discharging the secondary battery 90 to a predetermined voltage value by the electronic load.

When the secondary battery 90 is not used to be empty (to the minimum dischargeable charge amount or SOC of about 0%) and the capacity remains, the OCV value β on the low SOC side used for the OCV analysis cannot be acquired. However, the charger 20 can measure the OCV value β on the low SOC side necessary for accurate analysis by first performing the discharge using the electronic load, and can acquire the OCV data including this value.

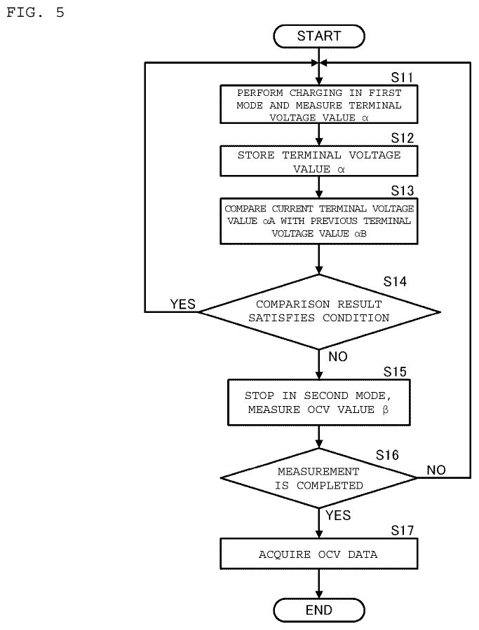

FIG. 5 is a flowchart illustrating an example of the method of acquiring OCV data according to the first embodiment of the present disclosure. Note that, since the specific description of each processing of the flowchart illustrated in FIG. 5 has been made in the description of the above-described configuration, detailed description thereof is omitted here except for necessary portions. In addition, although the charger 20 will be mainly described hereinafter, each processing is performed by each functional unit constituting the charger 20 as described above.

The charger 20 charges the secondary battery 90 in the first mode (with the first time period as a (minute) and the predetermined current value as I (C)), and measures the terminal voltage value α for mode selection immediately after charging (S11). The charger 20 stores the terminal voltage value α (S12).

The charger 20 compares the current terminal voltage value αA with the immediately previous terminal voltage value αB (S13). The immediately previous terminal voltage value αB is a terminal voltage value one charge cycle before (when charging is performed in the immediately previous first mode).

If the comparison result satisfies a condition for omission of the second mode (S14: YES), the charger 20 does not shift to the second mode and continues to execute the first mode (S11).

When the comparison result does not satisfy the condition for omission of the second mode (S14: NO), the charger 20 shifts to the second mode. Specifically, the charger 20 stops charging for the second time period, and measures the OCV value β immediately after the lapse of the second time period (S15).

After measuring all the OCV values β in the SOC range used for the OCV analysis, the charger 20 completes the measurement. If the measurement has not been completed (S16: NO), the charger 20 returns to the first mode and continues the charging and measurement.

When the measurement is completed (S16: YES), the charger 20 acquires a plurality of the OCV values β measured in the process of charging described above as OCV data (S17).

A charger and a method of acquiring OCV data according to a second embodiment of the present disclosure will be described with reference to the drawings. Note that the charger and the method of acquiring OCV data according to the second embodiment of the present disclosure are different from the charger and the method of acquiring OCV data according to the first embodiment in that a range in which OCV value measurement is omitted is determined using a voltage change rate with respect to SOC of a positive electrode active material and a voltage change rate with respect to SOC of a negative electrode active material forming the secondary battery. Other parts of the charger and the method of acquiring OCV data according to the second embodiment are similar to those of the charger and the method of acquiring OCV data according to the first embodiment, and description of similar parts is omitted.

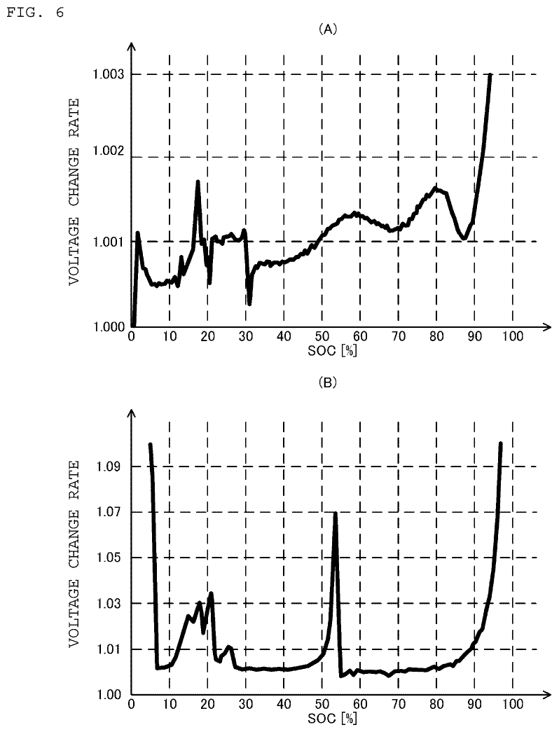

FIG. 6(A) is a graph showing an example of the voltage change rate with respect to the SOC of the positive electrode active material of the secondary battery according to the second embodiment of the present disclosure. FIG. 6(A) is an example in which a positive electrode active material (Li(NiMnCo)O₂) of a layered rock salt type is used as a positive electrode active material. FIG. 6(B) is a graph showing an example of the voltage change rate with respect to the SOC of the negative electrode active material of the secondary battery according to the second embodiment of the present disclosure. FIG. 6(B) is an example in which graphite is used as the negative electrode active material.

As shown in FIGS. 6(A) and 6(B), when the positive electrode active material (Li(NiMnCo)O₂) of the layered rock salt type is used as the positive electrode active material and graphite is used as the negative electrode active material, there are maximum points of the voltage change rate between 10% to 30%, between 50% to 60%, and between 80% to 100% of the SOC in a characteristic curve of the voltage change rate with respect to the SOC.

The charge control unit 21 and the measuring unit 22 shift from the first mode to the second mode and measure the OCV value β when the SOC is in the range of 10% to 30%, the range of 50% to 60%, and the range of 80% to 100%. The charge control unit 21 and the measuring unit 22 do not shift to the second mode in the other ranges, and continuously execute the first mode.

The voltage change rate is large in a predetermined SOC range including the maximum point of the voltage change rate. Therefore, it is necessary to measure the OCV value β in the second mode from the viewpoint of error suppression. On the other hand, the voltage change rate is small outside the predetermined SOC range including the maximum point. Therefore, the measurement of the OCV value β in the second mode is not necessary from the viewpoint of error suppression. In addition, the measurement of the OCV value β is not performed so that a time reduction effect can be obtained.

Since such processing is performed, the charger according to the second embodiment can reduce acquisition time of OCV data while suppressing an increase in error of the OCV data.

Further, in the charger according to the second embodiment, the execution of the second mode can be omitted also when the SOC is in the range of 50% to 60%.

The charger according to the second embodiment may perform the measurement of the OCV value β in the second mode only in two ranges of a low SOC range (for example, the SOC range of 0% to 20%) and a high SOC range (for example, the SOC range of 80% to 100%).

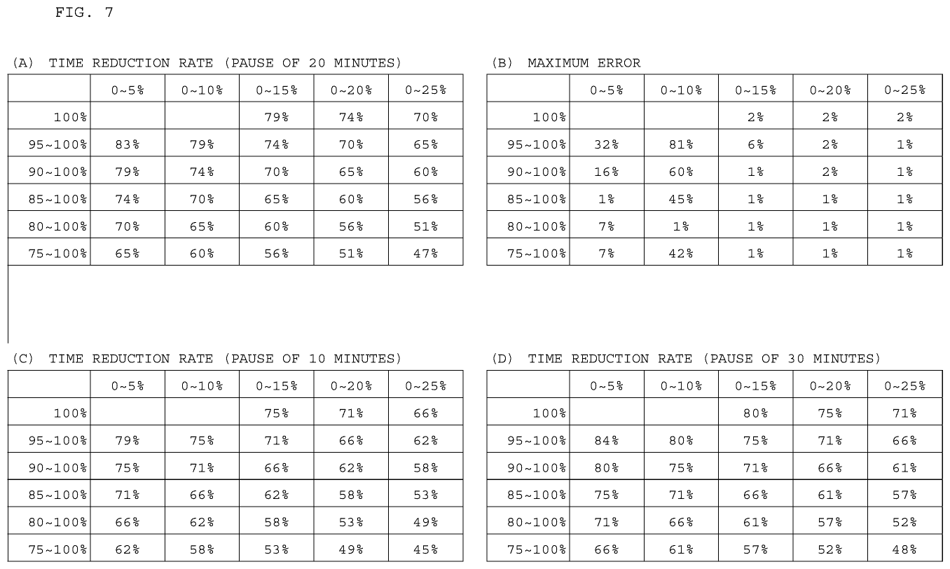

FIGS. 7(A), 7(C), and 7(D) are tables showing a relationship between a time reduction rate and a combination of the SOC ranges in which the second mode is performed, and FIG. 7(B) is a table showing a relationship between the combination of the SOC ranges in which the second mode is performed and the maximum error. FIG. 7(A) shows a case where a relaxation time (pause time) is 20 minutes, FIG. 7(C) shows a case where the relaxation time (pause time) is 10 minutes, and FIG. 7(D) shows a case where the relaxation time (pause time) is 30 minutes.

As shown in FIG. 7(B), when the measurement of the OCV value β in the second mode is performed only in the two ranges of the low SOC range (for example, the SOC range of 0% to 20%) and the high SOC range (the SOC range of 80% to 100%), the maximum error can be suppressed to about 1%, and the time reduction rate of about 70% can be obtained. Note that the range of the SOC for executing the second mode is not limited thereto, and can be appropriately set based on allowable maximum error and a target time reduction rate.

Further, in the charger according to the second embodiment, the high SOC range may be excluded from the execution target of the second mode, and the second mode may be executed only in SOC 100%. That is, the charger according to the second embodiment executes the second mode only in the low SOC range and SOC 100%.

Also with such processing, as shown in the time reduction rate in FIGS. 7(A), 7(C), and 7(D) and the maximum error in FIG. 7(B), it is possible to suppress an increase in the error of the OCV data while further reducing the acquisition time of OCV data.

A charger and a method of acquiring OCV data according to a third embodiment of the present disclosure will be described with reference to the drawings. Note that the charger and the method of acquiring OCV data according to the third embodiment of the present disclosure are different from the charger and the method of acquiring OCV data according to the second embodiment in terms of setting of a low SOC range. The other parts of the charger and the method of acquiring OCV data according to the third embodiment of the present disclosure are similar to those of the charger and the method of acquiring OCV data according to the second embodiment, and description of similar parts will be omitted.

As shown in FIG. 6(B) described above, a voltage change amount of a negative electrode active material is extremely large in an SOC range of 0% to 5%. Therefore, when the method of the first embodiment described above is simply adopted, the OCV value β in the second mode is measured in a case where a voltage change rate is equal to or larger than a reference value, and thus this section becomes a target section of the second mode, and the measurement frequency of the OCV value β increases. As a result, a time reduction effect is likely to decrease. Therefore, the charger according to the third embodiment performs the following processing.

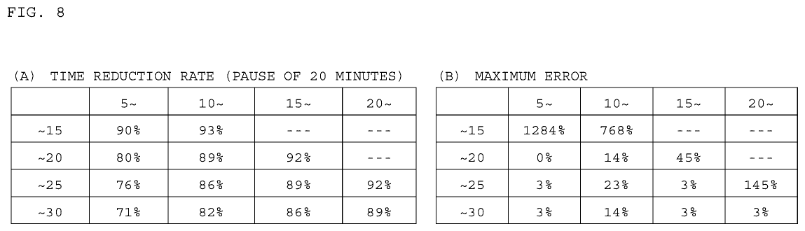

FIG. 8(A) is a table showing a relationship between a time reduction rate and a combination of the lowest SOC and the highest SOC in the low SOC range in which the second mode is performed, and FIG. 8(B) is a table showing a relationship between the maximum error and the combination of the lowest SOC and the highest SOC in the low SOC range in which the second mode is performed.

As shown in FIGS. 8(A) and 8(B), when measurement of the OCV value β in the second mode is not performed in the SOC range of 0% to 5%, it is possible to achieve the error of about 0% while achieving a time reduction effect of 80% or more.

Therefore, the charger according to the third embodiment can suppress an increase in the error of OCV data while further reducing acquisition time of OCV data by setting the minimum SOC in the low SOC range to 5%.

Note that, as shown in FIGS. 8(A) and 8(B), in a first setting mode in which an SOC range of 10% to 25% is set to the low SOC range and a second setting mode in which an SOC range of 15% to 25% is set to the low SOC range, the second setting mode has a smaller error although the number of measurement points of the OCV value β is smaller. This is considered to be because the negative electrode active material has four maximum points in the SOC range of 10% to 30% as shown in FIG. 6(B). This is considered to be because fitting has been performed erroneously using a maximum point on the lowest SOC side as a maximum point around SOC 5% in such a characteristic.

As described above, for a positive electrode active material and the negative electrode active material having many maximum points in the SOC range of 10% to 30%, such misfitting can be suppressed by causing the low SOC range to include a range around SOC 30% in which the voltage change rate is relatively small.

Therefore, the charger according to the third embodiment can further suppress the error by setting the SOC range that includes maximum points of the voltage change rate of the positive electrode active material and the voltage change rate of the negative electrode active material and has relatively small voltage change rates as the SOC range in which the second mode is performed.

The present disclosure is described in further detail according to an embodiment.
<1> A charger including:
a measuring unit that measures terminal voltage values α for mode selection and OCV values β with respect to a lithium ion secondary battery;
a storage unit that stores the measured terminal voltage values α for mode selection and the measured OCV values β;
a determination unit that determines selection between a first mode and a second mode based on the terminal voltage value α for mode selection;
a charge control unit that performs charge control of the lithium ion secondary battery in the first mode or the second mode based on a result of the determination; and
an output unit that outputs at least one of the OCV values β measured in a charging process as OCV data,
wherein the first mode is a mode in which the lithium ion secondary battery is charged at a predetermined current value for a first time period, and the terminal voltage value α of the lithium ion secondary battery immediately after a lapse of the first time period is measured,
the second mode is a mode in which the charging is stopped for a second time period after execution of the first mode, and the OCV value β of the lithium ion secondary battery immediately after a lapse of the second time period is measured,
the determination unit
compares a current terminal voltage value αA measured in the first mode with a previous terminal voltage value αB measured in the immediately previous first mode,
determines not to shift to the second mode in a case where

$$α A / α B < ( a \times I / 250 ) + 1$$

$$( 0.5 \leq a \leq 3 , 0.4 \leq I \leq 2.4 , and 0.6 \leq a \times I \leq 1.2 )$$

when the first time period is a (minute) and the predetermined current value is I (C), and
determines to shift to the second mode in a case where

$$α A / α B \geq ( a \times I / 250 ) + 1$$

$$( 0.5 \leq a \leq 3 , 0.4 \leq I \leq 2.4 , and 0.6 \leq a \times I \leq 1.2 ) ,$$

and
the measuring unit measures the OCV values β in the second mode.
<2> The charger according to <1>, further including an electronic load connectable to the lithium ion secondary battery,
wherein the charge control unit discharges the lithium ion secondary battery to a predetermined voltage value by the electronic load, and then starts the charge control in the first mode.
<3> The charger according to <1> or <2>, wherein
the charge control unit and the measuring unit
acquire a characteristic curve of a voltage change rate with respect to Soc based on a ratio between the terminal voltage value αA and the terminal voltage value αB, and
execute the measurement of the OCV values β in the second mode in predetermined SOC ranges respectively including a plurality of maximum points in the characteristic curve.

<4> The charger according to <3>, wherein the charge control unit and the measuring unit execute the measurement of the OCV values β in the second mode in the predetermined SOC range including at least one maximum point in the characteristic curve and in the SOC 100%.

<5> The charger according to <3>, wherein
when it is known that the lithium ion secondary battery connected to the charger is a secondary battery in which a positive electrode material is a layered rock salt type material and a negative electrode material is a graphite material,
the charge control unit and the measuring unit execute the measurement of the OCV values β in the second mode in the SOC range of 5% to 20% and the SOC 100%.
<6> A method of acquiring OCV data, the method including:
a measurement step of measuring terminal voltage values α for mode selection and OCV values β with respect to a lithium ion secondary battery;
a storage step of storing the measured terminal voltage values α for mode selection and the measured OCV values β;
a determination step of determining selection between a first mode and a second mode based on the terminal voltage value α for mode selection;
a charge control step of performing charge control of the lithium ion secondary battery in the first mode or the second mode based on a result of the determination; and
an output step of outputting at least one of the OCV values β measured in a charging process as OCV data,
wherein the first mode is a mode in which the lithium ion secondary battery is charged at a predetermined current value for a first time period, and the terminal voltage value α of the lithium ion secondary battery immediately after a lapse of the first time period is measured,
the second mode is a mode in which the charging is stopped for a second time period after execution of the first mode, and the OCV value β of the lithium ion secondary battery immediately after a lapse of the second time period is measured,
the determination step includes comparing a current terminal voltage value αA measured in the first mode with a previous terminal voltage value αB measured in the immediately previous first mode,
determining not to shift to the second mode in a case where

$$α A / α B < ( a \times I / 250 ) + 1$$

$$( 0.5 \leq a \leq 3 , 0.4 \leq I \leq 2.4 , and 0.6 \leq a \times I \leq 1.2 )$$

when the first time period is a (minute) and the predetermined current value is I (C), and
determining to shift to the second mode in a case where

$$α A / α B \geq ( a \times I / 250 ) + 1$$

$$( 0.5 \leq a \leq 3 , 0.4 \leq I \leq 2.4 , and 0.6 \leq a \times I \leq 1.2 ) ,$$

in the measurement step, the OCV values β are measured in the second mode, and
at least one of the measured OCV value β is output as the OCV data.

### DESCRIPTION OF REFERENCE SYMBOLS

20: Charger
21: Charge control unit
22: Measuring unit
23: Storage unit
24: Determination unit
25: Output unit
90: Secondary battery
231: Mode selection voltage value storage unit
232: OCV value storage unit
290: Charge terminal

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A charger comprising:
a measuring unit that measures terminal voltage values α for mode selection and OCV values β with respect to a lithium ion secondary battery;
a storage unit that stores the measured terminal voltage values α for mode selection and the measured OCV values β;
a determination unit that determines selection between a first mode and a second mode based on the terminal voltage value α for mode selection;
a charge control unit that performs charge control of the lithium ion secondary battery in the first mode or the second mode based on a result of the determination; and
an output unit that outputs at least one of the OCV values β measured in a charging process as OCV data,
wherein the first mode is a mode in which the lithium ion secondary battery is charged at a predetermined current value for a first time period, and the terminal voltage value α of the lithium ion secondary battery immediately after a lapse of the first time period is measured,
the second mode is a mode in which the charging is stopped for a second time period after execution of the first mode, and the OCV value β of the lithium ion secondary battery immediately after a lapse of the second time period is measured,
the determination unit
compares a current terminal voltage value αA measured in the first mode with a previous terminal voltage value αB measured in the immediately previous first mode,
determines not to shift to the second mode in a case where
$$α A / α B < ( a \times I / 250 ) + 1$$
$$( 0.5 \leq a \leq 3 , 0.4 \leq I \leq 2.4 , and 0.6 \leq a \times I \leq 1.2 )$$
when the first time period is a (minute) and the predetermined current value is I (C), and
determines to shift to the second mode in a case where
$$α A / α B \geq ( a \times I / 250 ) + 1$$
$$( 0.5 \leq a \leq 3 , 0.4 \leq I \leq 2.4 , and 0.6 \leq a \times I \leq 1.2 ) ,$$
and
the measuring unit measures the OCV values β in the second mode.

2. The charger according to claim 1, further comprising an electronic load connectable to the lithium ion secondary battery,
wherein the charge control unit discharges the lithium ion secondary battery to a predetermined voltage value by the electronic load, and then starts the charge control in the first mode.

3. The charger according to claim 1, wherein
the charge control unit and the measuring unit
acquire a characteristic curve of a voltage change rate with respect to Soc based on a ratio between the terminal voltage value αA and the terminal voltage value αB, and
execute the measurement of the OCV values β in the second mode in predetermined SOC ranges respectively including a plurality of maximum points in the characteristic curve.

4. The charger according to claim 3, wherein the charge control unit and the measuring unit executes the measurement of the OCV values β in the second mode in the predetermined SOC range including at least one maximum point in the characteristic curve and in the SOC 100%.

5. The charger according to claim 3, wherein
when it is known that the lithium ion secondary battery connected to the charger is a secondary battery in which a positive electrode material is a layered rock salt type material and a negative electrode material is a graphite material,
the charge control unit and the measuring unit execute the measurement of the OCV values β in the second mode in the SOC range of 5% to 20% and the SOC 100%.

6. A method of acquiring OCV data, the method comprising:
a measurement step of measuring terminal voltage values α for mode selection and OCV values β with respect to a lithium ion secondary battery;
a storage step of storing the measured terminal voltage values α for mode selection and the measured OCV values β;
a determination step of determining selection between a first mode and a second mode based on the terminal voltage value α for mode selection;
a charge control step of performing charge control of the lithium ion secondary battery in the first mode or the second mode based on a result of the determination; and
an output step of outputting at least one of the OCV values β measured in a charging process as OCV data,
wherein the first mode is a mode in which the lithium ion secondary battery is charged at a predetermined current value for a first time period, and the terminal voltage value α of the lithium ion secondary battery immediately after a lapse of the first time period is measured,
the second mode is a mode in which the charging is stopped for a second time period after execution of the first mode, and the OCV value β of the lithium ion secondary battery immediately after a lapse of the second time period is measured,
the determination step includes comparing a current terminal voltage value αA measured in the first mode with a previous terminal voltage value αB measured in the immediately previous first mode,
determining not to shift to the second mode in a case where
$$α A / α B < ( a \times I / 250 ) + 1$$
$$( 0.5 \leq a \leq 3 , 0.4 \leq I \leq 2.4 , and 0.6 \leq a \times I \leq 1.2 )$$
when the first time period is a (minute) and the predetermined current value is I (C), and
determining to shift to the second mode in a case where
$$α A / α B \geq ( a \times I / 250 ) + 1$$
$$( 0.5 \leq a \leq 3 , 0.4 \leq I \leq 2.4 , and 0.6 \leq a \times I \leq 1.2 ) ,$$
in the measurement step, the OCV values β are measured in the second mode, and
at least one of the measured OCV value β is output as the OCV data.
